(19) United States
(12) Patent Application Publication
(10) Pub. No.: US 2014/0342531 A1
(43) Pub. Date: Nov. 20, 2014

(54) Adhesive Sheet for Semiconductor Wafer Processing, Method for Processing of Semiconductor Wafer Using Sheet

(71) Applicant: LINTEC Corporation, Tokyo (JP)

(72) Inventors: Tomochika Tominaga, Tokyo (JP); Takashi Akutsu, Tokyo (JP)

(21) Appl. No.: 14/362,933

(22) PCT Filed: Dec. 5, 2012
(86) PCT No.: PCT/JP2012/081543

§ 371 Date: Jun. 5, 2014

(30) Foreign Application Priority Data
Dec. 6, 2011 (JP) 2011-267306
Dec. 28, 2011 (JP) 2011-288689

(51) Int. Cl. H01L 21/683; H01L 21/78; C09J 7/02; H01L 21/304

(52) U.S. Cl. CPC H01L 21/6836; H01L 21/304; H01L 21/78; C09J 7/02
USPC 438/464; 428/355 R; 428/339; 451/41

(57) ABSTRACT

To provide an adhesive sheet for wafer processing that satisfies characteristics such as: (1) protecting an uneven circuit surface during grinding with an adhesive force that is not excessively weak; (2) being easy to remove after processing; and (3) leaving very little adhesive residue on the wafer, and that can preferably be used as a removable BG sheet or the like. This adhesive sheet for wafer processing is characterized in having a substrate and an adhesive layer formed on the substrate, the adhesive layer having an adhesive polymer (A) and a polyrotaxane (B) having a linear-chain molecule passing through the opening of the at least two cyclic molecules, and having a block group at both ends of the linear-chain molecule, the adhesive polymer (A) and the cyclic molecule of the polyrotaxane (B) being linked together to form a crosslinked structure.

### TECHNICAL FIELD

The present invention relates to the adhesive sheet for semiconductor wafer processing, and further specifically relates to a surface protection sheet for protecting the wafer surface. Also, the present invention relates to the adhesive sheet for the semiconductor wafer processing preferably used for holding the wafer and chips when producing the semiconductor chip by dividing the semiconductor wafer formed with the circuit into each chip.

### DESCRIPTION OF THE RELATED ART

The electronic devices of recent days put importance on the portability, and has tendency to be thinner and more compact. Also, it is demanded to have higher capacity and faster calculation. Therefore, it has tendency to form a multilayered chip without changing the size of the semiconductor device; and the thinning of the semiconductor wafer for producing the chip which is the constitutional member thereof is in progress. Conventionally, the wafer had the thickness of 350 μm or so, however it is demanded to have 50 to 100 μm or even less.

Therefore, the semiconductor wafer is carried out with the backside grinding after the circuit forming step in order to make the thickness thinner and uniform. During the backside grinding, in order to protect the circuit formed on the surface, the adhesive sheet for wafer processing also called as a back grind (BG) sheet is adhered on the circuit face. Such BG sheet is demanded to securely protect the circuit face during the backside grincing, to have adhesiveness such that the grinding water can be prevented from infiltrating, and also to be easily releasable without leaving the adhesive residue after the backside grinding is completed.

Thus, as for the BG sheet, the adhesive layer having a re-releasable property using the energy ray curable adhesive agent or the water swelling type adhesive agent is proposed. Such BG sheet reduces the adhesive force and becomes easily releasable due to the energy ray irradiation or the water swelling of the adhesive layer after the backside grinding. However, when using these BG sheet, it is necessary to have special step such as energy ray irradiation or the water swelling of the adhesive layer when releasing, thus the process was complicated and caused the cost increase.

Therefore, the weak adhesive re-releasable type BG sheet capable of reducing the number of steps and capable of releasing without the special steps such as energy ray irradiation or the water swelling or so is used. As for the property demanded, (1) it has adhesive property so that it does not contaminate the circuit surface by being released during the backside grinding step; (2) it is easy to re-release after the processing; and (3) it has only little adhesive residue on the wafer. In order to accomplish (2) and (3), it is considered to increase the elasticity of the adhesive agent. However, the surface of the semiconductor wafer is formed with the roughness such as the circuit and the bumps or so, the adhesive agent having high elasticity has difficulty following such roughness, hence the space is generated, which causes the peeling, and the grinding water may infiltrate from the space in some cases. That is, the demanded property of above mentioned (1) may not be sufficiently satisfied. That is, BG sheet using the adhesive agent with the high elasticity has a drawback that it can only be applied to a smooth wafer.

Recently, the bumps and the circuit are formed at very close position to the end part of the semiconductor wafer, thus in order to prevent the infiltration of the grinding water to the circuit face, it is demanded to have a high following property against the bumps and the circuit. Therefore, the BG sheet which can only be applied to the smooth wafer is failing to respond to the market's demand. As for the means to soften the adhesive agent in order to provide the roughness following property to the adhesive layer, the means to reduce the crosslinking density of the adhesive agent, or the means to blend the plasticizer or so are considered. However, when such means are employed, there is a problem that the uncrosslinked component or the plasticizer contaminates the circuit as the residues. That is, the demanded property of above mentioned (3) may not be sufficiently satisfied. Also, in the predicting method which is recently used widely, the BG sheet is adhered to the face having the kerf which has been carried out with half cut dicing, hence the adhesive agent tends to remain at the edge part of the kerf, and even if it is the adhesive agent with certain degree of high elasticity, the adhesive residues tends to be easily generated. Also, by adhering the dicing sheet to the circuit face, the step of carrying out the cutting and the separation from the backside is known, however even in such step, the property of the above mentioned (1) to (3) was demanded for the dicing sheet.

In the patent article 1 (JP Patent Application Laid Open No. 2001-234136), the adhesive sheet for re-releasing used for the semiconductor wafer processing, wherein the adhesive layer is constituted by the acrylic based polymer having the content of the low molecular weight component with the molecular weight of 10⁵ or less is 10 wt % or less is disclosed. However, in order to suppress the content of the low molecular weight component as such, it is necessary to strictly control the molecular weight distribution, and requires high levels of technology for the equipment and the production condition or so. Also, it contains the below problems as well. That is, even when the molecular weight distribution is strictly controlled, in order to reduce the low molecular weight component, the molecular weight of the acrylic based polymer must be set to 900000 or higher or so which is high. Also, in order to reduce the residue, it is a must to form a three dimensional net structure body by crosslinking the acrylic based polymer. However, when the constitution of which the high molecular weight polymer is crosslinked is employed, the elasticity of the adhesive layer rises, and in some case, the roughness following property to the circuit face is deteriorated.

Also, recently, along with the circuit inside the electronic device becoming high density, it is demanded to improve the mounting technology of the semiconductor chip has the circuit face with the spherical bump with the diameter of several hundred μm or so made of solder or so used for the binding of the semiconductor chip and the substrate. Usually, the bump is bound in high density with the semiconductor wafer in advance. By grinding such backside of such wafer with the bump, the pressure difference caused by the height difference between the parts where the bump is present and the part where the bump is not present directly influences the wafer backside, and it causes a crack or a sink which is called dimple at the wafer backside. Eventually, this will destroy the semiconductor wafer. Also, the area where the adhesive layer and the wafer are not in contact occurs at the bottom part of the bumps, which caused the floating or a peeling of BG sheet, and to cause the infiltration of the grinding water.

Hence, instead of making the adhesive layer thick, it is proposed to provide an intermediate layer between the substrate film of the surface protection sheet and the adhesive layer for absorbing and easing the bump (The patent articles 2 and 3).

In such constitution, it is not demanded to reduce the adhesive residue at the intermediate layer which does not directly contact with the circuit face, hence sufficient flexibility can be provided, and the intermediate layer can absorb the projection. On the other hand, as for the adhesive layer which directly contacts with the circuit face, since a sufficient flexibility is provided to the intermediate layer, a sufficient aggregation property for reducing the residue can be provided. Such adhesive layer has poor flexibility, but by controlling the thickness so that it does not compromise the flexibility of the intermediate layer, both of the absorbency of the projection and the reduction of the adhesive residue can be accomplished as BG sheet as a whole.

However, in such constitution, for providing the intermediate layer having different material and production method in addition to the adhesive layer leads to an increase of the steps, and also to the increase of the cost.

On the other hand, such problem can be overcome, if the intermediate layer is not provided and that the height difference can be absorbed by the single layer or the multilayer of the adhesive layer.

However, in order to exhibit a necessary flexibility for the absorbency of the bumps, the aggregation property of the adhesive layer needs to be designed low. In such case, when releasing the adhesive sheet, the residue tends to easily occur at the adherend surface due to the destruction of the adhesive layer. On the other hand, if the aggregation property of the adhesive layer is maintained in order to prevent the destruction of the adhesive layer, the projection embedding property tends to decline.

Therefore, for the adhesive sheet having the layer for absorbing the projection only by the adhesive layer, it was extremely difficult to accomplish both contradicting characteristic, which are the suppression of the adhesive agent residue and the absorbency of the projection.

### [Patent Article 1] Japanese Patent Application Laid Open No. 2001-234136

### [Patent Article 2] Japanese Patent No. 4054113

### [Patent Article 3] Japanese Patent No. 4413551

### DISCLOSURE OF INVENTION

### Problem to be Solved by the Invention

The first object of the present invention is to provide the adhesive sheet for the wafer processing which is preferably used as the re-releasable BG sheet or so, and satisfies the characteristics such as (1) it protects the circuit face having the roughness with the adhesive force which is not too weak when grinding, (2) it is easy to re-release after the processing, and (3) it has few adhesive residues to the wafer.

Also, the second object of the present invention is to provide the adhesive sheet for the semiconductor wafer processing which is preferably used as the re-releasable BG sheet capable of suppressing the residue of the adhesive layer and that the projection of the adhesive layer can be absorbed, even when the projections such as bumps or so are formed at the adhering face of the wafer, without making the production step complicated.

### Means for Solving the Problems

As a result of a keen study to solve the above object, the present inventors have put their attention to the possibility of solving the above mentioned (3) by increasing the gel fraction of the adhesive agent. Also, the adhesive agent having high gel fraction has high elasticity in general, thus has a possibility to simultaneously solve the object (2) mentioned in above. The gel fraction is controlled by the number of the crosslinked structure inside the adhesive agent. On the other hand, the flexibility is influenced by the mobility of the polymer constituting the adhesive agent. Therefore, while having the crosslinked structure, if this structure is relatively flexible, the above demands can be satisfied. That is, the above mentioned demands (1) to (3) can all be satisfied if the adhesive agent has high gel fraction and certain degree of flexibility. Also, in order to solve the second object, the present inventors has carried out a keen examination to accomplish both of providing the flexibility for absorbing the projection embedding property and ensuring the aggregation property.

Then, the present inventors have put their attention to polyrotaxane of which the ring-shaped molecule can move within certain range. Polyrotaxane has a structure in which a linear-chain molecule passes through the cyclic molecule, and the movement of the cyclic molecule is controlled within certain range. That is, by presenting the polyrotaxane structure in the crosslinked structure, the flexibility may be provided to the adhesive agent without lowering the gel fraction by maintaining the crosslinked structure. Based on such findings, the present inventors obtained the adhesive sheet which solves the objects regarding the objects of the above mentioned (1) to (3) and the projection embedding property of the adhesive agent, by incorporating the polyrotaxane structure in which the cyclic molecule is constrained but is allowed to move, into the crosslinked structure of the adhesive agent.

That is, the gist of the present invention for solving the above mentioned objects are as described in below.

(1) An adhesive sheet for wafer processing comprising a base film and an adhesive layer formed thereon, wherein

said adhesive layer includes an adhesive polymer (A) and polyrotaxane (B) having at least two cyclic molecules and a linear-chain molecule passing through an opening of the cyclic molecules wherein the linear-chain molecule has blocking groups at both ends thereof, and

the adhesive polymer (A) and the cyclic molecule of polyrotaxane (B) are bonded to form a crosslinked structure.

(2) The adhesive sheet for wafer processing as set forth in (1), wherein

said adhesive polymer (A) has reactive functional group, said cyclic molecule has a reactive functional group, and the reactive functional group of said adhesive polymer (A) and the reactive functional group of said cyclic molecule forms a crosslinked structure by binding directly or indirectly.

(3) The adhesive sheet for wafer processing as set forth in (1) or (2), wherein storage elasticity at 25° C. of said adhesive layer is 2.5 MPa or less.

(4) The adhesive sheet for wafer processing as set forth in any one of (1) to (3), wherein an adhesive force when releasing from a silicon wafer mirror face while the sheet being cut into a size having a width of 25 mm is 5000 mN/25 mm or less.

(5) The adhesive sheet for wafer processing as set forth in any one of (2) to (4), wherein each of the reactive functional group of said adhesive polymer (A) and polyrotaxane (B) forms the crosslinked structure by binding via a crosslinking agent (C) comprising a crosslinking group capable of reacting with the reactive functional group of said adhesive polymer (A) and with the reactive functional group of said polyrotaxane (B).

(6) The adhesive sheet for wafer processing as set forth (5), wherein the reactive functional group of said adhesive polymer (A) and the reactive functional group of polyrotaxane are the same functional group, and

when the number of the reactive functional group comprised in the adhesive polymer (A) is taken as 1, a relative ratio α of the number of the reactive functional group comprised in polyrotaxane (B) to the number of the reactive functional group comprised in the adhesive polymer (A) is taken as α, and a relative ratio β of the number of the crosslinking group comprised in the crosslinking agent (C) to the number of the reactive functional group comprised in the adhesive polymer (A) is taken as β, then the adhesive layer satisfies a relation of 1+α−β≦1.5.

(7) The adhesive sheet for wafer processing as set forth in (5) or (6), wherein the reactive functional group of said adhesive polymer (A) and polyrotaxane (B) are hydroxyl group, and the crosslinking group of said crosslinking agent (C) is isocyanate group.

(8) The adhesive sheet for wafer processing as set forth in any one (1) to (7), wherein a breaking elongation is 100% or more when a thickness of said adhesive layer is 1 mm.

(9) The adhesive sheet for wafer processing as set forth in any one of (1) to (8), wherein a gel fraction of said adhesive layer is 90% or more.

(10) A method for processing a semiconductor wafer comprising a step of adhering a circuit surface of the semiconductor wafer formed with a circuit on a surface to the adhesive layer of the adhesive sheet for wafer processing as set forth in any one of (1) to (9), and a step of backside processing of the semiconductor wafer.

(11) The method for processing the semiconductor wafer as set forth in (10) wherein the backside processing of said semiconductor wafer is a backside grinding.

(12) A method for processing a semiconductor wafer comprising a step of adhering the semiconductor wafer formed with the circuit on a surface to the adhesive layer of the adhesive sheet for wafer processing as set forth in any one (1) to (9), and a step of dicing the semiconductor wafer.

(13) A production method of a semiconductor chip including steps of

forming a groove having a depth of cut shallower than a wafer thickness from a semiconductor wafer surface formed with a circuit with a bump,

adhering the adhesive sheet as set forth in any one of (1) to (9) to said circuit formed face,

thinning the wafer thickness by carrying out a backside grinding of said semiconductor wafer, then

dividing into each chip and picking up the chip.

(14) An adhesive sheet for semiconductor wafer processing comprising a base film and an adhesive layer formed on one side thereof, wherein

a thickness of the adhesive layer is 100 to 300 μm,

said adhesive layer is formed of a crosslinked structure by binding below identified adhesive polymer (A) and polyrotaxane (B) via a crosslinking agent (C),

said adhesive polymer (A) and polyrotaxane (B) has same reactive functional group, and

when the number of the reactive functional group comprised in the adhesive polymer (A) is taken as 1, a relative ratio α of the number of the reactive functional group comprised in polyrotaxane (B) to the number of the reactive functional group comprised in the adhesive polymer (A) is taken as α, and a relative ratio β of the number of the crosslinking group comprised in the crosslinking agent (C) to the number of the reactive functional group comprised in the adhesive polymer (A) is taken as β, then the adhesive layer satisfies a relation of 1+α−β≦0.8.

(A) An adhesive polymer comprising a reactive functional group.

(B) Polyrotaxane having at least two cyclic molecules and a linear-chain molecule passing through opening of the cyclic molecules wherein the linear-chain molecule has blocking groups at both ends thereof

(15) The adhesive sheet for semiconductor wafer processing as set forth in (14), wherein a gel fraction of said adhesive layer is 40% or more.

(16) The adhesive sheet for semiconductor wafer processing as set forth in (14) or (15), wherein said adhesive layer has multilayered structure.

(17) The adhesive sheet for semiconductor wafer processing as set forth in any one of (14) to (16), wherein said reactive functional group is hydroxyl group, and said crosslinking agent (C) is isocyanate based crosslinking agent.

(18) The adhesive sheet for semiconductor wafer processing as set forth in any one of (14) to (17) used for a grinding of a backside of the semiconductor wafer.

(19) The adhesive sheet for semiconductor wafer processing as set forth in (18), wherein a substance of said semiconductor wafer is provided with a projection having a height of 50 μm or higher on a surface.

(20) The production method of a thinned semiconductor wafer comprising steps of,

adhering the adhesive sheet for semiconductor wafer processing as set forth in any one of (14) to (17) to a projection face of the semiconductor wafer provided with projections on one side, and

grinding one face of the semiconductor wafer which is not adhered with said adhesive sheet for semiconductor wafer processing.

(21) The production method of the thinned semiconductor wafer as set forth in (20), wherein a height of said projection is 50 μm or more.

### The Effect of the Invention

In the adhesive layer of the adhesive sheet for the wafer processing of the present invention, the adhesive polymer forms the crosslinked structure, and at least to a part of the crosslinked structure, the polyrotaxane structure is present. That is, the adhesive polymers are indirectly bonded with each other via the structure of polyrotaxane. Therefore, the adhesive layer itself has high aggregation property, and the residues do not remain on the adherend after the releasing of the adhesive sheet. Also, the cyclic molecule in the rotaxane structure has mobility along the linear-chain molecule while being constrained, thus the adhesive agent easily deformed by incorporating into the crosslinked structure, and shows the excellent following property against the roughness of the wafer such as circuit or so, furthermore it is easily re-releasable without the energy ray irradiation or water swelling or so.

### BRIEF DESCRIPTION OF THE DRAWINGS

FIG. 1 is a diagram of the crosslinked structure of the adhesive layer.

### THE EMBODIMENTS FOR CARRYING OUT THE INVENTION

Hereinafter, the present invention will be described in further detail by referring to the FIGURE. The adhesive sheet for the wafer processing according to the present invention comprises the base film and the adhesive layer formed thereon, and the adhesive layer includes the crosslinked structure in which the adhesive polymer is crosslinked via the polyrotaxane structure.

### (The Base Film)

As for the base film used in the adhesive sheet of the present invention, it is not particularly limited, and a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, an ethylene/vinyl acetate copolymer film, an ionomer resin film, an ethylene(meth)acrylic acid copolymer film, an ethylene(meth)acrylic acid ester copolymer film, a polystyrene film, a polycarbonate film, a fluoro resin film, a low density polyethylene (LDPE) film, a linear low density polyethylene (LLDPE) film, or hydrogenated and modified film thereof may be used. Also, the crosslinking film thereof may be used as well. The above mentioned base film may be alone, or it may be a composite film combining two or more thereof

The thickness of the base film is not particularly limited, and it is usually 10 to 1000 μm, preferably 30 to 500 μm, and more preferably 50 to 300 μm. At the base film surface provided with the adhesive layer, in order to improve the adhesiveness between the adhesive layers, the corona treatment may be carried out or a primer layer or so may be provided.

### (The Adhesive Layer)

The adhesive layer includes the crosslinked structure wherein the adhesive polymer is crosslinked via the polyrotaxane structure. That is, polyrotaxane is present in at least in a part of the structure in which the adhesive polymers crosslinks with each other, and it forms a structure of which the adhesive polymers are bonding with each other via the cyclic molecule of polyrotaxane. Polyrotaxane and the adhesive polymer may form the crosslinked structure by binding directly with the reactive functional group of each other; or may form the crosslinked structure by binding each reactive functional group of the adhesive polymer and polyrotaxane via the crosslinking agent. Hereinafter, the adhesive layer may be simply referred as the adhesive agent.

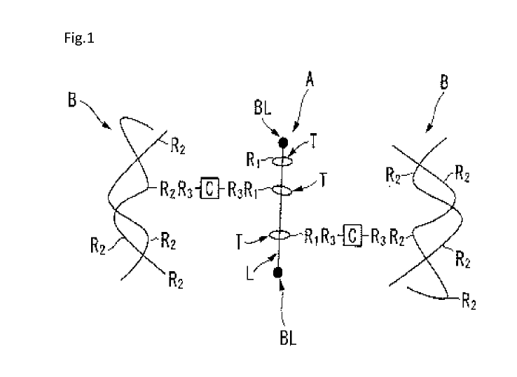

Hereinafter, the embodiment wherein the crosslinked structure is formed by bonding the adhesive polymer and polyrotaxane via the crosslinking agent will be used as a main example to describe in further detail. FIG. 1 is a diagram showing the crosslinked structure of which the adhesive polymer (A) and polyrotaxane (B) are bonded via the crosslinking agent (C). FIG. 1 shows the linear-chain molecule (L) passing through the opening of at least two cyclic molecule T having the reactive functional group R₁; and forming the crosslinked structure by bonding polyrotaxane (B) comprising blocking group BL at both ends of the linear-chain molecule L, and the adhesive polymer (A) comprising the reactive functional group R₂, via the crosslinking agent (C) comprising the crosslinking group R₃ capable of reacting with reactive functional group R₁ and the reactive functional group R₂. However, the crosslinking structure may be formed by direct bonding of the adhesive polymer (A) and polyrotaxane (B).

### (The Adhesive Polymer)

As for the adhesive polymer, the known acrylic based polymer, the rubber based polymer, the silicone based polymer, and the urethane based polymer or so used for the adhesive agent can be used. Among these, the acrylic based polymer of which the reactive functional group can be easily introduced to the side chain is preferable. In order to form the crosslinked structure, the adhesive polymer comprises the reactive functional group in the molecule. The reactive functional group of the adhesive polymer is not particularly limited as long as it can react with the crosslinking agent for bonding, or it can directly react with the cyclic molecule of polyrotaxane; however those with the thermal reactiveness are preferable and hydroxyl group, carboxyl group, epoxy group, amino group, isocyanate group, vinyl group, acryloyl group or so may be mentioned. These reactive functional groups may be mixed with two or more thereof in the adhesive polymer. Among these reactive functional groups, the hydroxyl group is particularly preferable since it does not shift the adhesive layer to the acidic side or to the alkaline side, has excellent corrosion resistance, and has highly stable crosslink. Therefore, the reactive functional group R₂ of the adhesive polymer in FIG. 1 is preferably hydroxyl group.

The adhesive polymer is preferably the adhesive polymer (A) comprising two or more of said reactive functional groups in the molecule. Such adhesive polymer can be obtained by using the monomer comprising said reactive functional group as the monomer during the polymer preparation, or the reactive functional group may be introduced after the polymerization by the means of modification.

As for the adhesive polymer, the acrylic based polymer comprising the reactive functional group is particularly preferably used. As for the main monomer constituting the acrylic based polymer, (meth)acrylic alkyl ester or cycloalkyl ester acrylic acid having the carbon atoms of 1 to 18 of the alkyl group is used. As (meth)acrylic acid alkyl ester or cycloalkyl ester acrylic acid, methyl acrylate, methyl methacrylate, ethyl acrylate, ethyl methacrylate, propyl acrylate, propyl methacrylate, isopropyl acrylate, isopropyl methacrylate, n-butyl acrylate, n-butyl methacrylate, isobutyl acrylate, isobutyl methacrylate, n-hexyl methacrylate, 2-ethyl hexyl acrylate, 2-ethylhexyl methacrylate, cyclohexyl acrylate, lauryl methacrylate or so may be mentioned.

By copolymerizing the reactive functional group containing monomer which is copolymerizable with aforementioned main monomer, the reactive functional group is introduced in to the obtained acrylic based polymer. As the hydroxyl group containing monomer, 2-hydroxyethyl acrylate, 2-hydroxyethyl methacrylate, 2-hydroxypropyl acrylate, 2-hydroxypropyl methacrylate, 2-hydroxybutyl acrylate and 2-hydroxybutyl methacrylate or so may be mentioned. As the carboxyl group containing monomer, acrylic acid, methacrylic acid, and itaconic acid or so, may be mentioned. As the epoxy group containing monomer, glycidyl methacrylate, glycidyl acrylate or so may be mentioned. Further, in addition to the above mentioned, the reactive functional group may be introduced using carboxyl group, amino group, isocyanate group or so. In case of using the hydroxyl group containing monomer, and using the isocyanate based crosslinking agent as the crosslinking agent, there is an effect to facilitate the reaction between the hydroxyl group and the isocyanate based crosslinking agent by using polymerizable monomer having carboxyl group or amino group. Also, the compound having for example vinyl group, acryloyl group or so may be introduced to the side chain of the polymer after the polymerization reaction.

The adhesive polymer can be obtained by copolymerizing the above mentioned (meth)acrylate and the reactive functional group containing monomer by a normal method. However, in addition to these monomers, vinyl formate, vinyl acetate, styrene or so may be copolymerized in a ratio of small amount (for example, 10 wt % or less, preferably 5 wt % or less).

The content of the constituting unit derived from the monomer comprising the reactive functional group R₂ in such adhesive polymer is preferably 0.1 to 20 wt %, more preferably 0.5 to 15 wt %, and particularly preferably 2 to 10 wt %. Here, the content of the constituting unit is calculated by the ratio (%) of the weight of the monomer of said constituting unit in the whole weight of the monomer component used during the polymerization of the adhesive polymer (same applies to the following).

The weight average molecular weight of the adhesive polymer (A) is the measured value by GPC (Gel Permeation Chromatography), and it is preferably 100,000 to 3,000,000, and particularly preferably 500,000 to 2,000,000. If the weight average molecular weight is less than 100,000, the aggregation property, the stress relaxation and the durability of the adhesive layer may not be sufficient. On the other hand, if the weight average molecular weight exceeds 3,000,000, the compatibility with polyrotaxane which will be described in below will be deteriorated, and the crosslinked structure may not be formed effectively, or the optical characteristic of the total light transmittance rate or so of the adhesive layer may decline, or the stress relaxation property may not be sufficiently ensured due to the decline of the compatibility with polyrotaxane.

Also, the glass transition temperature (Tg) of the adhesive polymer (A) is preferably 50° C. or less, and particularly it is 30° C. or less. If the glass transition temperature (Tg) exceeds 50° C., the compatibility with polyrotaxane will be deteriorated, and a sufficient flexibility of the adhesive layer may not be exhibited. Further, from the point of improving the projection embedding property of the high bump wafer, the transition temperature (Tg) of the adhesive polymer (A) is preferably 30° C. or less, more preferably 10° C. or less, and particularly preferably −10° C. or less. In case the glass transition temperature (Tg) is high, the adhesive force of the adhesive layer declines, and it may be released from the semiconductor wafer, or water used for the processing of the semiconductor wafer may infiltrate to the boundary between the adhesive layer and the wafer. Also, the glass transition temperature of the adhesive polymer (A) is preferably −60° C. or higher, and more preferably −50° C. or higher. As the glass transition temperature (Tg) of the adhesive polymer (A) being −60° C. or higher, the adhesive layer will have suitable aggregation property, and will prevent the excessive increase of the adhesive force, further the residue to the adherend surface will be suppressed.

In order to control the glass transition temperature (Tg) of the adhesive polymer (A) within such range, the adhesive polymer (A) preferably comprises the monomer of the homopolymer having the glass transition temperature of −25° C. or higher such as methyl acrylate, methyl methacrylate, vinyl acetate, ethyl acrylate, acrylonitrile, styrene or so as the monomer. The content of the constitution unit derived from the monomer of the homopolymer having the glass transition temperature of −25° C. or higher is preferably 1 to 50 wt %, and more preferably 5 to 40 wt %.

The blending amount of the adhesive polymer in the above mentioned adhesive layer is usually 30 to 98 wt % and more preferably 40 to 95 wt % in the solid portion of the adhesive agent. Further, from the point of improving the projection embedding property of the high bump wafer, the blending amount of the adhesive polymer is preferably 70 to 99.5 wt %, and preferably 75 to 99 wt % in the solid portion of the adhesive agent.

### (Polyrotaxane)

Polyrotaxane is an integral molecule of which the linear-chain molecule passes through the opening of at least two cyclic molecules, and has the blocking groups at the both ends of said linear-chain molecule. Further, for the adhesive agent of present invention, said adhesive polymer is bonded to the cyclic molecule of polyrotaxane. When the bonding is made via the cyclic molecule of polyrotaxane, the bonding part can move while being constrained and suitable flexibility can be provided to the adhesive agent. Therefore, polyrotaxane used in the present invention is preferably polyrotaxane (B) comprising the reactive functional group on the cyclic molecule.

The above mentioned polyrotaxane (B) can be obtained by the conventional method (for example by the method recited in JP Patent Application Laid Open No. 2005-154675).

As shown in FIG. 1, the linear-chain molecule L of polyrotaxane is included in the cyclic molecule T, and it is a molecule or substance which can be integrated by mechanical bonding not by chemical bonding such as covalent bond or so, further it is not particularly limited as long as it is linear. Note that, in the present specification, “the linear” of “the linear-chain molecule” refers to linear shape substantially. That is, as long as the cyclic molecule T can move on the linear-chain molecule L, the linear-chain molecule L may have a branched chain.

As for the linear-chain molecule L of polyrotaxane, for example polyethylene glycol, polypropylene glycol, polyisoprene, polyisobutylene, polybutadiene, polytetrahydrofurane, polyacrylate, polydimethyloxane, polyethylene, polypropylene or so are preferable; and two or more of these linear-chain molecules L may be mixed in the adhesive composition.

The number average molecular weight of polyrotaxane is preferably 3,000 to 300,000, particularly preferably 10,000 to 200,000, and further preferably 20,000 to 100,000. If the number average molecular weight is less than 3,000, the amount of movement of the cyclic molecule T on the linear-chain molecule L becomes small, and sufficient flexibility and the stress relaxation of the adhesive layer may not be obtained. Also, if the number average molecular weight exceeds 300,000, the solubility of polyrotaxane to the solvent, and the compatibility of polyrotaxane with the adhesive polymer may be compromised.

The cyclic molecule T of polyrotaxane is not particularly limited, as long as it can form the inclusion complex with the above mentioned linear-chain molecule L, and can move on said linear-chain molecule L. Note that, in the present specification, “the cyclic” of “the cyclic molecule” refers to the substantial ring shape. That is, as long as it can move on the linear-chain molecule L, the ring-shaped L does not need to be completely closed ring, and for example it may have a helical structure.

As the cyclic molecule T of polyrotaxane, a cyclic polymer such as cyclic polyether, cyclic polyester, cyclic polyether amine or so, or cyclodextrin such as α-cyclodextrin, β-cyclodextrin, γ-cyclodextrin or so may be preferably mentioned. As the specific example of the above mentioned cyclic polymer, crown ether or the derivative thereof, calixarene or the derivative thereof, cyclophane or the derivative thereof, cryptand or the derivative thereof or so may be mentioned.

Similar to the reactive functional group R₂ of said adhesive polymer, as the reactive functional group R₁ comprised in cyclic molecule T of polyrotaxane, hydroxyl group, carboxyl group, epoxy group, amino group, isocyanate group, vinyl group, acrylonitrile group or so may be mentioned; the hydroxyl group is particularly preferable since it does not shift the adhesive layer to the acidic side or to the alkaline side, and is less likely to cause a coloring or so due to the reaction, further it has excellent bonding stability. Two or more of these reactive functional groups R₁ may mixed in polyrotaxane.

The content of the reactive functional group R₁ is preferably 1.0×10⁻⁴ to 1.0×10⁻² mol per 1 g of solid portion of polyrotaxane, and it is more preferably 5.0×10⁻⁴ to 5.0×10⁻³ mol per 1 g.

As for the cyclic molecule T, among the above mentioned, cyclodextrin such as α-cyclodextrin, β-cyclodextrin, γ-cyclodextrin or so are preferable, and more preferably it is α-cyclodextrin. Two or more of these cyclic molecules T may be mixed in polyrotaxane.

In case of using cyclodextrin as the cyclic molecule T, said cyclodextrin may be introduced with the substituent group which can improve the solubility of polyrotaxane. The substituent group is a functional group capable of being introduced to cyclodextrin by binding with the hydroxyl group of cyclodextrin via for example ester bonding or so. As for the preferable substituent group, for example, acetyl group, alkyl group, trityl group, tosyl group, trimethyl silane group, phenyl group or so; further polyester chain, oxyethylene chain, alkyl chain, acrylic acid ester chain or so may be mentioned. The number average molecular weight of the substituent group is preferably 100 to 10,000, and 400 to 2,000 is particularly preferable.

The introduction rate (the substitution degree) of the substituent group to the hydroxyl group of cyclodextrin is preferably 10 to 90%, and particularly preferable 30 to 70%. If the introduction rate is less than 10%, the improvement of the solubility of polyrotaxane to the solvent is not sufficient; and if the introduction rate exceeds 90%, the content ratio of the reactive functional group R₁ of polyrotaxane declines, and the reaction of polyrotaxane with said adhesive polymer (A) or the crosslinking agent (C) may not be sufficient. Also, even in case the substituent group has the reactive functional group which will be discussed in below, if the introduction rate exceeds 90%, it may become difficult to control the introduction amount due to the steric effect.

Note that, the reactive functional group R₁ may not be directly bonded to the cyclic molecule T. That is, the above mentioned reactive functional group R₁ may be present via the above mentioned substituent group such as acetyl group or so. By taking such embodiment, the distance from the cyclic molecule T is controlled, thereby the bulky substituent group having the reactive functional group R₁ can be introduced by avoiding the steric effect between the cyclic molecule T; It is also possible to introduce substituents each having one or more reactive groups contained in a substituent which has an alkyl chain, an ether chain, and an ester chain, or an oligomer of the foregoing, and which is formed by polymerization starting from reactive groups which avoids steric hindrance with the cyclic molecules T.

As for the specific explanation of the above, for example, the hydroxyl group which is present in cyclodextrin itself is the reactive functional group R₁; and if hydroxypropyl group is added to the hydroxyl group, then hydroxyl group of hydroxypropyl group is included as the reactive functional group R₁ as well. Further in case the ring opening polymerization of ε-caprolactone is carried out via the hydroxyl group of said hydroxypropyl group, the hydroxyl group is formed at the opposite end of polyester chain obtained by the ring opening polymerization. In such case, the hydroxyl group is included in the reactive functional group R₁.

Note that, from the point of both accomplishing the solubility and the reactiveness of polyrotaxane, it is particularly preferable that the cyclic molecule T is introduced with the substituent group of alkaline chain, ether chain, ester chain, or the oligomer chain thereof; and the substituent group comprises one or more reactive functional group.

In case of using cyclodextrin as the cyclic molecule T, the remaining ratio of hydroxyl group in the cyclic molecule T is preferably 4 to 90%, and particularly preferably 20 to 70%. The remaining ratio of hydroxyl group is expressed in percentage which is the ratio that the number of hydroxyl group of cyclodextrin reduced by the introduction of the substituent group is divided by the number of the hydroxyl group originally comprised in cyclodextrin. If the remaining ratio of the hydroxyl group is less than 4%, polyrotaxane (B) may not react sufficiently with the above mentioned adhesive polymer or the crosslinking agent. On the other hand, if the remaining ratio exceed 90%, many crosslinks are generated in the same cyclic molecule T, hence the cyclic molecule T itself will be a crosslink point, thus the mobility is significantly constrained, and sufficient flexibility may not be secured.

The blocking group BL of polyrotaxane is not particularly limited as long as it is a group which maintains the condition wherein the cyclic molecule T is penetrated by linear-chain molecule L. As such group, a bulky group, ionic group or so may be mentioned.

Specifically, the blocking group of polyrotaxane is dinitrophenyl groups, cyclodextrins, adamantane groups, trityl groups, fluoresceins, pyrenes, anthracenes or the like, or a main chain, side chain or the like of a polymer having a number average molecular weight of 1,000 to 1,000,000; and two or more of these blocking groups may be mixed in polyrotaxane. As the polymer having the number average molecular weight of 1,000 to 1,000,000, for example polyamide, polyimide, polyurethane, polydimethylcyloxane, polyacrylate or so may be mentioned.

The blending amount of polyrotaxane in the above mentioned adhesive agent is usually 0.5 to 50 wt %, preferably 1 to 40 wt %, and more preferably 2 to 35 wt % in the solid portion of the adhesive layer.

The amount of cyclic molecules T that form an inclusion complex with the linear-chain molecule L in a state where the cyclic molecules T are penetrated by the linear-chain molecule L ranges preferably from 0.1 to 60%, more preferably, 1 to 50%, and in particular from 5 to 40%, in case the amount of cyclic molecules T that form an inclusion complex with the linear-chain molecule L in a state where the cyclic molecules T are penetrated by the linear-chain molecule L is 100%.

The maximum inclusion amount of cyclic molecules T is determined on the basis of the length of the linear-chain molecule and the thickness of the cyclic molecules. The maximum inclusion amount is determined experimentally in a case where, for instance, the linear-chain molecule is polyethylene glycol, and the cyclic molecules are α-cyclodextrin molecules (refer to Macromolecules 1993, 26, 5698-5703).

### (The Crosslinked Structure)

As discussed in above, the adhesive layer of the present invention includes the crosslinked structure wherein the adhesive polymer is crosslinked via the polyrotaxane structure. That is, should it be explained using FIG. 1, the structure in which the adhesive polymers A are crosslinked are formed by having the cyclic molecule T of polyrotaxane B in at least to a part of a structure in which the adhesive polymers A crosslinks with each other. In such structure, the cyclic molecule T has mobility along the linear-chain molecule L while being constrained, hence the distance between the adhesive polymers A with each other bonded to the cyclic molecules T which are different cyclic molecules T of the same polyrotaxane shown in FIG. 1 will elongate and shorten. As a result, the crosslinked structure as a whole, it comprises a flexibility, and also thought to cause the characteristic which easily follows to the deformation (hereinafter, it may be referred as “a crosslinked space variability”. The adhesive polymer A and polyrotaxane may form the crosslinked structure by bonding directly, or it may form the crosslinked structure by bonding the adhesive polymer A and polyrotaxane B via the crosslinking agent. Note that, the cyclic molecule T is not constrained to the linear-chain molecule L via binding, and each of the adhesive polymer A shown in FIG. 1 are not bonded against each other. Therefore, these adhesive polymers A are not crosslinked, but it takes a pseudo-crosslinked state. By having such pseudo-crosslinked structure, the cyclic molecule T obtains the mobility along the linear-chain molecule L while being constrained, and the crosslinked space variability can be exhibited. On the other hand, in case two adhesive polymers A are bonded to the same cyclic molecule T, then the adhesive polymers A are bonded with each other, hence the true crosslinked structure will be formed. Also, in case the adhesive agent comprises the crosslinking agent, two adhesive polymers A are bonded via the crosslinking agent, and the true crosslinked structure is formed. In the adhesive agent, such pseudo-crosslinked structure and true crosslinked structure may be mixed. Also, in case that the adhesive agent does not comprise the crosslinking agent capable of connecting the adhesive polymers A with each other, and also that all of the cyclic molecules are connected with the adhesive polymer A with one or less bonding; then only the pseudo-crosslinked structure exist, and the true crosslinked structure should not be present, however the present invention refers to crosslinked structure including the structure only with the pseudo-crosslinked structure.

In case polyrotaxane and the adhesive polymer directly reacts to form the crosslinked structure, the reactive functional group R₁ of polyrotaxane and the reactive functional group R₂ of the adhesive polymer are the groups capable of reacting with each other. For example, by setting one of the reactive functional group to hydroxyl group or carboxyl group, and other reactive functional group to isocyanate group, polyrotaxane and the adhesive polymer reacts directly, thereby the crosslinked structure wherein the adhesive polymer is bonded via polyrotaxane is formed.

Also, the adhesive polymer and polyrotaxane may form the crosslinked structure by binding via the below described crosslinking agent (C).

As such, when the crosslinked structure is formed between the adhesive polymers via polyrotaxane, polyrotaxane exist by being incorporated into the three dimensional network structure, thus the residues scarcely remains to the adherened when the adhesive agent is released; and also the high elongation rate and the high roughness following property which is the effect of the present invention can be obtained since the structure wherein the molecular chain passes through the cyclic molecule in the three dimensional network structure shows the crosslinked space variability.

The adhesive agent can be obtained by directly reacting the reactive functional group of the adhesive polymer (A) and the reactive functional group of polyrotaxane (B). In such case, if the crosslinked degree (the gel reaction) of the adhesive agent is to be controlled, the blending amount of polyrotaxane is changed, or polyrotaxane having two or more kinds of different reactive functional group is used. However, if the blending amount of polyrotaxane (B) is changed, the amount of the adhesive polymer reacting against one polymer molecule also changes. That is, if the blending amount of polyrotaxane is changed, the crosslinked space variability of polyrotaxane (the flexibility of the adhesive agent) will be influenced. Therefore, if the crosslinked degree (the gel reaction) of the adhesive agent is to be controlled, the flexibility of the adhesive agent changes and it will become difficult to control both independently. Also, it is possible to control the amount of polyrotaxane incorporated into the crosslinked structure of the adhesive agent by using polyrotaxane (B) having two or more kinds of different reactive functional group in one molecule, however it is time consuming to prepare plurality of polyrotaxane.

Therefore, it is preferable to control the crosslinked degree by adding the crosslinking agent (C). The crosslinking agent (C) directly binds the adhesive polymers against each other, or it binds via polyrotaxane, thus the crosslinked degree is determined unambiguously by the amount of the crosslinking agent used. That is, the crosslinked degree can be independently controlled by the blending amount of the crosslinking agent (C). On the other hand, the flexibility of the crosslinked degree is thought to be caused by the crosslinked space variability of polyrotaxane, and it can be controlled mainly by the blending amount of polyrotaxane. Therefore, the crosslinked degree and the flexibility of the adhesive agent could be controlled independently by the blending amount of the crosslinking agent and polyrotaxane. Therefore, in the present invention, it is preferable that the adhesive polymer (A) and polyrotaxane (B) are bonded via the crosslinking agent (C).

In such case, the reactive functional group R₂ of the adhesive polymer (A) and the reactive functional group R₁ of polyrotaxane (B) are preferably the same, so that the adhesive polymer (A) and polyrotaxane (B) does not directly react, and further preferably the reactive functional groups are hydroxyl groups. Thereby, the crosslinking agent will only need to have two or more of the single reactive functional groups in the molecule without selecting the functional group capable of reacting with both of R₁ and R₂. Also, if cyclodextrin which is suitable for polyrotaxane formation is used as the cyclic molecule T, then it is easy to use hydroxyl group for the reactive functional group R₂. Further, if R₁ and R₂ are both hydroxyl group, it becomes easy to generate the bond between the adhesive polymer and the cyclic molecule of polyrotaxane (B) when using the isocyanate based crosslinking agent having high reactivity with the hydroxyl group.

### (The Crosslinking Agent)

As for the crosslinking agent (C), the compound of difunctional or more having the crosslinkable group R₃ can be used which is capable of reacting with the reactive functional group R₁ of polyrotaxine and the reactive functional group R₂ of the adhesive polymer. Also, it may take a constitution wherein the crosslinking agent (C) comprises the functional group capable of reacting only with the reactive functional group R₁ as the crosslinkable group R₄, and the crosslinkable group R₅ capable of reacting with at least the reactive functional group R₂; or it may be the opposite of this.

Hereinafter, the crosslinking agent (C) comprising the crosslinkable group R₃ which can reactive with the reactive functional group R₁ and the reactive functional group R₂ will be used as an example to explain. Note that, as mentioned in above, it is not necessary to select the functional group as the R₃ which can react with two different R₁ and R₂, as long as the reactive functional group R₂ of the adhesive polymer (A) and the reactive functional group R₁ of polyrotaxane are the same.

As the crosslinkable group R₃ comprised in the crosslinking agent (C), hydroxyl group, carboxyl group, epoxy group, amino group, isocyanate group, vinyl group, acryloyl group or so may be mentioned; and isocyanate group is particularly preferable. Two or more of these crosslinkable group R₃ may be mixed in the crosslinking agent (C).

When the reactive functional group R₁ of polyrotaxane is hydroxyl group, the reactive functional group R₂ of the adhesive polymer (A) is hydroxyl group, and the crosslinkable group R₃ of the crosslinking agent (C) is isocyanate group, the reaction is easy and proceeds at a controllable speed, thus it is easy to balance the reactivity of the reactive functional group R₁ and the reactive functional group R₂. Also, the compound having these crosslinkable groups has high versatility, and it has wide variety of types of material and thus easy to obtained, hence the cost can be suppressed low.

As the crosslinking agent (C), for instance, isocyanate based compounds such as xylylene diisocyanate, hexamethylene diisocyanate, tolylene diisocyanate, isophorone diisocyanate or the adduct thereof (for example, trimethylolpropane adduct); epoxy based compounds such as ethylene glycol diglycidyl ether, propylene glycol diglycidyl ether, 1,6-hexanediol glycidyl ether or the adduct thereof; or aziridine based compounds such as N,N-hexamethylene-1,6-bis(1-aziridine carboxyamide) or the adduct thereof may be mentioned. Preferred among the foregoing are isocyanate compounds.

The blending amount in the adhesive agent of the crosslinking agent (C) is determined based on the value of “1+α−β” which indicates the degree of the reactive functional group remaining after the crosslinking; and usually it is 1 to 20 wt %, preferably 2 to 25 wt %, and more preferably 3 to 20 wt % in the solid portion of the adhesive agent.

When the reactive functional group of the adhesive polymer (A) and the reactive functional group of polyrotaxane (B) are the same, and the number of the reactive functional group of the adhesive polymer (A) is 1, a relative ratio α of a number of the reactive functional group comprised in polyrotaxane (B) to the number of the reactive functional group comprised in the adhesive polymer (A) is taken as α, and a relative ratio β of the number of the crosslinking group comprised in the crosslinking agent (C) to the number of the reactive functional group comprised in the adhesive polymer (A) is taken as β, then the adhesive layer preferably satisfies a relation of 1+α−β≦1.2. Here, the number of the reactive functional group or the crosslinkable group comprised in each component is obtained by multiplying the number of the reactive functional group or the crosslinkable group per 1 parts by weight of the component thereof with the number of the parts by weight of the component thereof which was blended during the formation of the adhesive layer. As the reactive functional group of the adhesive polymer (A), the reactive functional group of polyrotaxane (B) and the crosslinkable group of the crosslinking agent (C) satisfies such relationship, the number of the crosslinkable group will not be in short supply against the reactive functional group. Thereby, most part of polyrotaxane (B) is incorporated in the three dimensional network structures, and the residue caused by polyrotaxane (B) which remained instead of being incorporated can be suppressed being generated on the adherend surface after the releasing of the sheet. Further, from the point of improving the projection embedding property of the high bump wafer, preferably the relationship of 1+α−β≦0.8 is satisfied. As for the range of this value, it is more preferably 1+α−β≦0.6, and further preferably 1+α−β≦0.55. By being within such range, the fine residues generated on the adherend surface which is called “particles” tends to be suppressed. Also, 1+α−β is preferably −2 or higher, and more preferably −1.5 or higher. If 1+α−β is too small, it means that the crosslinkable group is present excessively with respect to the reactive functional group (X), and the unreacted crosslinking agent (C) may remain in the adhesive layer, which may contaminate the adherend, and the remaining crosslinking agent may become a cause of the characteristic change over the time after the formation of the adhesive layer.

### (Other Components)

The adhesive agent includes the crosslinked structure formed of the above mentioned components (A), (B) and also (C) which is added depending on the needs; but in many cases the coating is difficult if it is only made of the components (A) to (C), thus the adhesive agent is coated as the diluted adhesive agent solution and then dried. As the preferable solvent used in such case, aliphatic hydrocarbons such as hexane, heptane, cyclohexane or the like; aromatic hydrocarbons such as toluene, xylene or the like; halogenated hydrocarbons such as methylene chloride, ethylene chloride or the like; alcohols such as methanol, ethanol, propanol, butanol, 1-methoxy-2-propanol or the like; ketones such as acetone, methyl ethyl ketone, 2-pentanone, isophorone, cyclohexanone or the like; esters such as ethyl acetate, butyl acetate or the like; or cellosolve solvents such as ethyl cellosolve or so may be mentioned.

The concentration viscosity of the adhesive solution prepared as such is not particularly limited, and may be appropriately selected depending on the circumstances, as long as it is within the range of which the coating is possible. Various additives, for instance antioxidants, ultraviolet absorbers, infrared absorbers, antistatic agents, spreading agents and the like, the tackifier, the pigment, the die, the filler, the energy ray curable resin, the photopolymerization initiator or so may also be added to form the adhesive agent solution. These other components may be included in the ratio of 10 wt % or less with respect to the entire solid portion forming the adhesive layer. Note that, when obtaining the adhesive agent solution, the addition of the solvents or so are not a necessary condition, and as long as the adhesive composition has a viscosity which is possible to coat, then the solvents may not be added. In such case, the adhesive agent will be handled as same as the adhesive agent solution.

### (The Physical Properties of the Adhesive Layer)

The breaking elongation when the thickness of the adhesive layer is 1 mm is preferably 100% or more. Thereby, the embedding property to the roughness of the adherend surface of the adhesive layer improves. The adhesive polymer increases the breaking elongation by the predetermined crosslinked space variability since it comprises the three dimensional network structure in which polyrotaxane (B) has been incorporated. Also, the adhesive layer is unlikely to be torn off during the releasing, thus the residues during the sheet releasing is efficiently suppressed. The breaking elongation is preferably 120% or more, and more preferably 140% to 500%. If the breaking elongation is too big, it is a result of the adhesive layer losing the aggregation property, and it tends to cause the increase of the residues to the adhesive layer to the adherend.

The gel fraction of the adhesive layer is preferably 90% or more, and more preferably 95% or more. Thereby, the generation of the residues to the adherend surface after the sheet releasing is efficiently suppressed. The gel fraction of the adhesive layer tends to increase when the blending amount of the above mentioned crosslinking agent increases. Also, from the point of improving the projection embedding property of the high bump wafer, it is preferable to have the gel fraction of the adhesive layer of 40% or more, and more preferably it is 50 to 99.9%.

The storage elasticity of the adhesive layer at 25° C. is preferably 0.1 MPa or more, and more preferably 0.2 to 3 MPa, and more preferably 0.3 to 2 MPa. Thereby, the adherend can be stably maintained, and the residues to the adherend surface after the sheet releasing can be efficiently suppressed. The storage elasticity of the adhesive layer tends to increase when the blending amount of the above mentioned crosslinking agent increases. The adhesive layer of the present invention has a structure in which the adhesive polymer is crosslinked via the polyrotaxane structure, thus the residues to the adherend surface is unlikely to occur.

The adhesive layer preferably does not include the energy ray curable resin. By taking such constitution, it will not have the energy ray curable property. Therefore, the step of releasing is done without the energy ray curing step after carrying out predetermined processing to the wafer, thereby as the energy ray curing step is omitted hence it is efficient. Note that, unless the effect of the present invention is not interfered, the energy ray curable resin may be blended in the adhesive layer.

### (The Adhesive Sheet for Wafer Processing)

The adhesive layer may be single layer made of above mentioned adhesive agent and the additives which is added if desired, or it may have multilayered structure of two or more layers. The thickness of the adhesive agent is not particularly limited, and usually it is 5 to 100 μm, preferably 10 to 80 μm, and more preferably 20 to 60 μm or so. If the thickness of the adhesive layer becomes thin, the adhesiveness or the surface protection function may decline. Also, in case the adhesive agent has the multilayered structure of two or more layers, the entire thickness of the adhesive agent may be within the above range, and the multilayered structure may have the thickness of 5 to 200 μm or so which includes said adhesive agent. Further, the adhesive layer may be formed on the one side of the above mentioned base film or it may be formed on the both face.

Further, from the point of improving the projection embedding property of the high bump wafer, the thickness of the adhesive layer is 100 to 300 μm, and preferably it is 100 to 250 μm. In such case, the adhesive layer may be single layer made of above mentioned adhesive agent and the additives which is added if desired, or it may have multilayered structure of two or more layers. In case the adhesive layer is formed by coating and drying, as the adhesive layer of the present invention is thick, in some case the drying takes a long time, thus it may not be efficient. Thus, it is preferable to form the whole adhesive layer by stacking two or more adhesive layers having thinner thickness which is formed separately. In this case, each of the adhesive layers has a characteristic of above mentioned adhesive layer. The thickness of each adhesive layers is usually 10 to 150 μm, and more preferably 25 to 100 μm, from the point of the drying efficiency and also as it does not increase the number of stacked layers too much.

As the thickness of the adhesive layer becomes thinner, the adhesiveness may decline, and the absorbency of the projections may not be exhibited sufficiently. In case the adhesive layer is too thick, there may be a trouble during the roll winding step or so. Further, the thickness of the adhesive layer is preferably thicker than the height of the projection, thereby the absorbency of the projection of the adhesive sheet of the present invention will be exhibited further more without being influenced by the rigidity of the base film. Also, between the base film and the adhesive layer, the flexible resin layer may be formed which is different from the adhesive layer.

On the opposite side from the side where the above mentioned adhesive layer of the base film, other adhesive layer maybe provided. Other adhesive layer as such is for example provided for adhering the adherend and the adhesive sheet to the flat supporting board during the processing of the adherend. The composition of other adhesive layer may be the same as the above mentioned adhesive layer, or it may be different composition.

Also, in order to protect the adhesive layer before the use of the adhesive sheet, the release sheet may be stacked. The release sheet is not particularly limited, and various sheets having releasable surface can be used. As for such release sheet, specifically, a polyethylene sheet, a polypropylene sheet, a polybutene sheet, a polybutadiene sheet, a polymethylpentene sheet, a polyvinyl chloride sheet, a vinyl chloride copolymer sheet, a polyethylene terephthalate sheet, a polybutylene terephthalate sheet, a polyurethane sheet, an ethylene/vinyl acetate copolymer sheet, an ionomer resin sheet, an ethylene/(meth)acrylic acid copolymer sheet, an ethylene/(meth)acrylic acid ester copolymer sheet, a polystyrene sheet, a polycarbonate sheet, a fluoro resin sheet, a low density polyethylene (LDPE) sheet, a linear low density polyethylene (LLDPE) sheet, or hydrogenated and modified sheet thereof may be used. Also, these crosslinking sheets may be used. The above mentioned release sheet may be used alone, or it may be a composite sheet combing two or more thereof

As the release sheet, the sheet carried out with the release treatment to the one side of the surface of the above mentioned sheet is preferable. As for the release agent used for the release treatment, it is not particularly limited, and silicone based, fluorine based, alkyd based, unsaturated polyester based, polyolefin based, wax based or so may be used. Particularly, a silicone based release agent is preferable as it tends to achieve low release force. If the sheet used for the release sheet has low surface tension itself as polyolefin sheet, and shows low release force against the adhesive layer, then the release treatment may not be carried out.

As for the method of the release treatment, the release agent is coated using a gravure coater, a meyer-bar coater, an air knife coater, or a roll coater or so to said film without the solvent, or by solvent diluting or emulsifying. Then, the release agent is heated, or irradiated with the ultraviolet ray or the electron beam for curing; thereby the release layer is formed.

The thickness of the above mentioned release sheet is preferably 12 μm or more, and more preferably 15 to 1000 μm, and particularly preferably 50 to 200 μm.

The adhesive force when releasing from a silicon wafer mirror face while the sheet being cut into a size having a width of 25 mm is 5000 mN/25 mm or less, and more preferably 100 to 4000 mN/25 mm, further preferably 300 to 3000 mN/25 mm or less, and particularly preferably 300 to 2500 mN/25 mm or less. Usually, if the adhesive force of the adhesive sheet increases, and the roughness following property tends to improve. This is because the adhesive force can compete with the force which tries to release the adhesive layer from adherend due to the roughness. However, when the adhesive force is high, the residue to the adherend tends to increase, and also the releasing of the adhesive sheet may become difficult, or the adherend may be damaged due to the releasing. The adhesive sheet of the present invention includes, as mentioned in above the crosslinked structure wherein the adhesive polymers are crosslinked via polyrotaxane, hence it can follow the roughness even if it has low adhesive force, and the residues to the adherend surface can be suppressed.

If the adhesive force is too low, the floating and the peeling may occur during the grinding of the adhesive sheet, hence the grinding water may infiltrate.

### (The Production of the Adhesive Sheet for the Wafer Processing)

The adhesive sheet for the wafer processing of the present invention can be produced by coating the adhesive agent forming the adhesive layer on the base film by known coating device to the appropriate thickness, and drying by applying the heat of 80 to 150° C. or so, thereby crosslinking the reactive functional group and the crosslinkable group of each component. As the coating device, a roll coater, a knife coater, a roll knife coater, a fountain die coater, a slot die coater, a reverse coater or so may be mentioned. On the adhesive layer, it is preferable to adhere the release sheet in order to protect the adhesive agent face. Also, it may be produced by providing the adhesive sheet on the release sheet and further transferring to the base film.

The adhesive sheet of the present invention can be used for the processing of the semiconductor wafer as shown in the following.

### (The Wafer Backside Grinding Method)

During the backside grinding of the wafer, the adhesive sheet for the wafer processing is stacked to the circuit face of the semiconductor wafer formed with the circuit on the front surface in order to protect the circuit surface while the backside grinding of the wafer and to have a predetermined thickness of the wafer.

The semiconductor wafer can be a silicon wafer, or a compound semiconductor wafer such as gallium arsenide or so. The formation of the circuit on the wafer surface can be performed by conventionally widely used various methods such as an etching method and a lift off method or so. Also, at the wafer surface, the projections such the bumps (the electrodes) or so may be formed, and the bump is formed by the plating or solder or so. The height of the projection is usually 50 μm or higher, and in many cases it is 50 to 500 μm or so. In case the adhesive sheet of the present invention is used to the semiconductor wafer formed with such projections, it is preferable since the absorbency of the projection thereof can be exhibited. The predetermined circuit is formed during the circuit forming step of the semiconductor wafer. The thickness of such wafer before the grinding is not particularly limited; however it is usually 500 to 1000 μm or so.

The backside grinding is carried out by the known means using the grinder and the vacuum table or so for fixing the wafer while the adhesive sheet is adhered. As the adhesive sheet has suitable breaking elongation and the storage elasticity, even if strong shear stress is applied to the wafer during the wafer backside grinding, the vibration of the wafer and the shift of the position can be prevented, and the wafer backside can be ground smooth and extremely thin. After the backside grinding step, the treatment to remove the fractured layer due to the grinding may be performed. The thickness of the semiconductor wafer after the backside grinding is not particularly limited, but preferably it is 10 to 300 μm, and particularly preferably 25 to 200 μm or so. Also, on the circuit face of the semiconductor wafer, the bumps for the conduction may be formed. The adhesive sheet of the present invention is highly effective to release and absorb the roughness of the bumps or so, and it can be particularly preferably used for the wafer comprising the bumps.

After the backside grinding step, the adhesive sheet is released from the circuit face. According to the adhesive sheet of the present invention, the adhesive layer securely holds the wafer during the backside grinding of the wafer, and the infiltration of the grinding water to the circuit face can be prevented. Also, during the releasing of the adhesive sheet, the adhesive agent residue remaining on the wafer surface can be reduced as well.

### (The Wafer Dicing Method)

The adhesive sheet for the present invention can be used as the dicing sheet as well. As for the adhesive sheet of the present invention, since the adhesive layer has roughness following property and the residue suppressing property, it can be suitably used as the dicing sheet for the dicing step by adhering to the wafer with the roughness at the adhering face.

When using as the dicing sheet, it is suitable for the case of adhering the adhesive sheet of the present invention to the surface of the wafer then cutting the wafer. The adhering of the dicing sheet is generally carried out by the device called a mounter; however it is not particularly limited.

The dicing method of the semiconductor wafer is not particularly limited. As for an example, the method of forming chips from a wafer by known methods such as a method using a rotating round blade of a dicer or so after fixing the peripheral portion of the dicing tape by the ring flame when dicing the wafer may be mentioned. Alternatively, it may be a dicing method using a laser light.

### (The Dicing Method by a Dicing Before Grinding Method)

Further, the adhesive sheet of the present invention is preferably used for making the wafer to a chip particularly by the dicing before grinding (DBG) method. Specifically, it is preferably used for the production method of the semiconductor chip including steps of

forming a groove having a depth of cut shallower than a wafer thickness from a semiconductor wafer surface formed with a circuit with a bump,

adhering the adhesive sheet to said circuit formed face as the surface protection sheet,

thinning the wafer thickness by carrying out a backside grinding of said semiconductor wafer, then

dividing into each chip and picking up the chip. Further specifically, it is used for the production method of the semiconductor chip comprising the following steps.

Step 1: Forming the groove from the wafer surface wherein said groove has a predetermined depth along the cutting position of the wafer which divides into plurality of circuits.

Step 2: Adhering the adhesive sheet of the present invention so that it covers entire surface of said wafer.

Step 3: Removing the bottom part of said groove and grinding the wafer backside until it reaches the predetermined thickness, then dividing into each chips. When grinding, the grinding is performed by supplying water (the grinding water) to the grinding surface in order to remove the grinding dusts and grinding heat. By using the adhesive sheet of the present invention at this point, since high sealing property can be obtained between the chip and the adhesive layer, the grinding water does not leak into the circuit surface; hence the contamination of the chip can be prevented. Also, for the DBG method, the adhesive residues tends to occur at the edge part (the boundary between the grooves where groove is not formed) of the groove as the surface protection sheet is adhered to the face where groove is formed, however since the adhesive agent of the present invention has high aggregation property, the adhesive residues of the edge part is unlikely to occur.

Then, the chips are picked up by the predetermined method. Also, the pickup of the chips can be performed by transferring the chip, which is aligned in the wafer form, to the other adhesive sheet, before the pickup of the chips.

When using the adhesive sheet of the present invention to the manufacturing step of the semiconductor device by such DBG method, a film having relatively high rigidity such as a polyethylene terephthalate film or a polyethylene naphthalate film or so is preferably used as the base film; in order to prevent the chip crack when forming the chip by the back side grinding and to prevent the calf width of the divided chips from shrinking.

### EXAMPLES

Hereinafter the present invention will be described based on the examples; however the present invention is not limited thereto. Note that, the evaluations of each physical properties were carried out as describe in the following.

### (The Adhesive Force Measurement)

Under the atmosphere of 23° C. and 50% RH, the adhesive sheet of the examples and the comparative examples were cut into the size having the width of 25 mm, and adhered to the mirror face of the silicon wafer having the diameter of 6 inch and the thickness of 600 μm by moving the roller having the weight of 5 kg back and forth for 1 time. Then, it was left for 20 minutes under the same atmosphere, and 180 degrees release adhesive force was measured at the speed of 300 mm/min.

### (The Gel Fraction Measurement)

On the release film (SP-PET381031 made by LINTEC Corporation), the adhesive agent of the examples and the comparative examples were coated, and carried out the drying, then carried out the adhering with the release film (SP-PET381031 made by LINTEC Corporation); thereby the adhesive agent single layer sheet which does not comprise the base film held between the release films were produced. After leaving the adhesive agent single layer sheet for one week under the atmosphere of 23° C. and 50% relative humidity, the adhesive agent single layer sheet of about 0.1 g was cutout from the adhesive agent single layer sheet, and was wrapped in a mesh (#400) of Tetron (product name). The non-gel fraction of the adhesive agent was extracted under reflux, with ethyl acetate as a solvent, in a Soxhlet extractor (lipid extractor, made by Tokyo Glass Kikai Co.). The gel fraction was calculated based on the ratio with respect to the initial weight.

### (The Dynamic Viscoelasticity Measurement)

The adhesive agent single layer sheet was produced as similar to the gel fraction measurement. Pluralities of the adhesive agent single layer sheets were stacked, and the lamination was repeated until the thickness reached 1 mm. The stacked adhesive agent thereof was measured using Advanced Rheometric Expansion System (made by Rheometric Scientific, Inc). In regards with the elasticity, the storage elasticity at −20 to 120° C. under the frequency of 1 Hz (6.28 rad/sec) was measured, and the value at 25° C. was taken.

### (The Breaking Elongation Measurement)

The adhesive agent single layer sheet was produced as similar to the gel fraction measurement. Pluralities of the adhesive agent single layer sheets were stacked, and the lamination was repeated until the thickness reached 1 mm. The sample thereof was cut into a size having the length of 100 mm, and the width of 15 mm, and was pulled to 0 to 400 mm at the speed of 200 mm/min using Autograph AG-1S 100N (made by Shimadzu Corporation). The value of the breaking elongation at that time was measured.

### (The Following Property of the Adherend Face Roughness)

The silicon chip having the size of 1 cm×1 cm with the thickness of 25 μm was placed on the silicon wafer, and the adhesive sheet was laminated thereon. After leaving for 24 hours at 23° C. and 60% relative humidity, then the width of the space generated as the adhesive sheet were unable to adhere (the area which were not able to contact since the adhesive agent generated at the bottom part of the step constituted by the silicon chip couldn't follow) was measured. Then, when the width thereof was 500 μm or less it was evaluated “good”, and if exceeded 500 μm then it was evaluated “poor”.

### (The Particle Measurement)

The adhesive sheet was laminated on the silicon wafer mirror face by applying a load using 5 kg roller which moves back and forth for 1 time, then it was left for 1 hour at 23° C. and 60% relative humidity; then the sheet sample was released at the release speed of 12 m/min and the release degree of 180°, and the measurement was carried out by the wafer surface inspection apparatus [S6600 (made by Hitachi Engineering Co., Ltd)], then the number with the residue having the size of 0.27 μm or larger on the wafer was measured.

### (The Confirmation of the Remaining Adhesive Agent at the Edge Part of the Half Cut Dicing Wafer)

The adhesive tape was adhered to the silicon wafer which has been carried out with half cut dicing, by using the tape laminator Adwill RAD-3510 (made by LINTEC Corporation), at the adhering speed of 5.0 mm/sec; then after leaving for 1 hour at 23° C. and 60% relative humidity, it was released at the angle of 180° at the release speed of 120 mm/min using Autograph AG-1S 100N (made by Shimadzu Corporation). The remaining adhesive agent at the kerf during the releasing was observed for 5 longitudinal positions and 5 horizontal positions using the electron microscope at the magnification of 1000×. If the remaining adhesive agent was not observed it was evaluated “good”, and if it was observed it was evaluated “bad”.

### Example 1

The adhesive agent mixed with 100 parts by weight of the acrylic based adhesive agent (having butyl acrylate and methyl methacrylate as the main component, and copolymer wherein the content of constituting unit derived from 2-hydroxyethylacrylate is 5 wt %, and the weight average molecular weight of 600,000 the glass transition temperature of −43.6° C., and the solid portion of 40 wt %); 10 parts by weight of the isocyanate based crosslinking agent (BHS-8515, the solid portion of 37.5 wt %, made by TOYO INK CO., LTD); and 9.6 parts by weight of polyrotaxane (SeRM Super Polymer A1000 made by Advanced Softmaterials Inc., the solid portion 35 wt %); was coated on the release material (SP-PET381031 made by LINTEC Corporation) so that the thickness after the drying becomes 40 μm, then dried for 1 minute at 100° C., thereby the adhesive layer was formed on the release material. The exposed face of this adhesive layer was adhered to the low density polyethylene film having the thickness of 110 μm, thereby the adhesive sheet was produced. Note that, the number of the parts by weight is the weight under the condition of solution (same applies hereinbelow as well). The physical properties of the adhesive layer and the result of adhering/releasing test of the adhesive sheet are shown in FIG. 1.

Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1. Note that, the method of calculation of 1+α−β will be shown in Table 2 by using the present example as one example. Also, the number of the reactive functional group (hydroxyl group) and the crosslinkable group (isocyanate group) per unit weight of each component are shown in Table 2.

### Example 2

The adhesive sheet was obtained as same as the example 1, except for using the adhesive agent mixing 100 parts by weight of the acrylic based adhesive agent as same as the example 1, 10 parts by weight of the isocyanate based adhesive agent (BHS-8515 made by TOYO INK CO., LTD), and 3.8 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 3

The adhesive sheet was obtained as same as the example 1, except for using the adhesive agent mixing 100 parts by weight of the acrylic based adhesive agent as same as the example 1, 8 parts by weight of the isocyanate based adhesive agent (BHS-8515 made by TOYO INK CO., LTD), and 6.1 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 4

The adhesive sheet was obtained as same as the example 1, except for using the adhesive agent mixing 100 parts by weight of the acrylic based adhesive agent as same as the example 1, 8 parts by weight of the isocyanate based adhesive agent (BHS-8515 made by TOYO INK CO., LTD), and 3.0 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 5

The adhesive sheet was obtained as same as the example 1, except for using the adhesive agent mixing 100 parts by weight of the acrylic based adhesive agent as same as the example 1, 10 parts by weight of the isocyanate based adhesive agent (BHS-8515 made by TOYO INK CO., LTD), and 19.2 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 6

The adhesive sheet was obtained as same as the example 1, except for using the adhesive agent mixing 100 parts by weight of the acrylic based adhesive agent as same as the example 1, 8 parts by weight of the isocyanate based adhesive agent (BHS-8515 made by TOYO INK CO., LTD), and 15.4 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 7

The adhesive sheet was obtained as same as the example 1, except for using the adhesive agent mixing 100 parts by weight of the acrylic based adhesive agent as same as the example 1, 4 parts by weight of the isocyanate based adhesive agent (BHS-8515 made by TOYO INK CO., LTD), and 15.4 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 8

The adhesive sheet was obtained as same as the example 1, except for using the adhesive agent mixing 100 parts by weight of the acrylic based adhesive agent as same as the example 1, 4 parts by weight of the isocyanate based adhesive agent (BHS-8515 made by TOYO INK CO., LTD), and 7.7 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 9

The adhesive sheet was obtained as same as the example 1, except for using the adhesive agent mixing 100 parts by weight of the acrylic based adhesive agent as same as the example 1, 4 parts by weight of the isocyanate based adhesive agent (BHS-8515 made by TOYO INK CO., LTD), and 3.0 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 10

The adhesive sheet was obtained as same as the example 1, except for using the adhesive agent mixing 100 parts by weight of the acrylic based adhesive agent as same as the example 1, 30.19 parts by weight of the isocyanate based adhesive agent (BHS-8515 made by TOYO INK CO., LTD), and 38.4 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Example 11

The adhesive sheet was obtained as same as the example 1, except for using the adhesive agent mixing 100 parts by weight of the acrylic based adhesive agent as same as the example 1, 40.3 parts by weight of the isocyanate based adhesive agent (BHS-8515 made by TOYO INK CO., LTD), and 76.8 parts by weight of polyrotaxane. Also, Table 1 shows the value of 1+α−β, a relative ratio α of a number of the hydroxyl group of polyrotaxane when the number of the hydroxyl group of the acrylic based adhesive polymer is 1, and a relative ratio β of the number of the isocyanate group of the isocyanate compound when the number of the hydroxyl group of the acrylic based adhesive polymer is 1.

### Comparative Example 1

The adhesive sheet was obtained as same as the example 1, except for using the adhesive agent mixing 100 parts by weight of the acrylic based adhesive agent as same as the example 1, and 20 parts by weight of the isocyanate based adhesive agent (BHS-8515 made by TOYO INK CO., LTD).

### Comparative Example 2

The adhesive sheet was obtained as same as the example 1, except for using the adhesive agent mixing 100 parts by weight of the acrylic based adhesive agent as same as the example 1, and 0.2 parts by weight of the isocyanate based adhesive agent (BHS-8515 made by TOYO INK CO., LTD).

TABLE 1
Table 1

| | | | | | Functional group Crosslinking group | | | |
|---|---|---|---|---|---|---|---|---|
| | | Adhesive composition | | | (*) relative ratio | | | |
| | | (parts by weight) | | | | | Corsslinking | |
| | | Adhesive | | Corsslinking | Adhesive | Polyrotaxane | agent | |
| | | polymer | Polyrotaxane | agent | polymer | (α) | (β) | 1 + α − β |
| Example | 1 | 100 | 9.6 | 10.0 | 1 | 0.25 | 0.99 | 0.26 |
| | 2 | 100 | 3.8 | 10.0 | 1 | 0.1 | 0.99 | 0.11 |
| | 3 | 100 | 6.1 | 8.0 | 1 | 0.16 | 0.79 | 0.37 |
| | 4 | 100 | 3.0 | 8.0 | 1 | 0.08 | 0.79 | 0.29 |
| | 5 | 100 | 19.2 | 10.0 | 1 | 0.5 | 0.99 | 0.51 |
| | 6 | 100 | 15.4 | 8.0 | 1 | 0.40 | 0.79 | 0.61 |
| | 7 | 100 | 15.4 | 4.0 | 1 | 0.40 | 0.4 | 1.00 |
| | 8 | 100 | 7.7 | 4.0 | 1 | 0.20 | 0.4 | 0.80 |
| | 9 | 100 | 3.0 | 4.0 | 1 | 0.08 | 0.4 | 0.68 |
| | 10 | 100 | 38.4 | 30.2 | 1 | 1.00 | 3 | −1.00 |
| | 11 | 100 | 76.8 | 40.3 | 1 | 2.00 | 4 | −1.00 |
| Comparative | 1 | 100 | | 20 | | | | |
| Example | 2 | 100 | | 0.2 | | | | |

| | | Adhesive layer physical property | | | | Adhering Releasing test | | |
|---|---|---|---|---|---|---|---|---|
| | | Adhesive | Gel | Storage | Breaking | Adherend | | Confirmation of |
| | | force | fraction | elasticity | elongation | following | | remaining |
| | | (N/25 mm) | (%) | MPa | (%) | property | Particle | adhesive agent |
| Example | 1 | 730 | 98.3 | 0.86 | 127 | Good | 1 | Good |
| | 2 | 620 | 98.6 | 1.2 | 122 | Good | 3 | Good |
| | 3 | 1735 | 98.2 | 0.37 | 189 | Good | 3 | Good |
| | 4 | 1770 | 98.3 | 0.39 | 181 | Good | 30 | Good |
| | 5 | 2300 | 97.9 | 0.78 | 145 | Good | 61 | Good |
| | 6 | 2360 | 97.1 | 0.19 | 125 | Good | 6631 | Good |
| | 7 | 3530 | 94.6 | 0.19 | 160 | Good | 6780 | Good |
| | 8 | 3200 | 96.2 | 0.22 | 148 | Good | 3159 | Good |
| | 9 | 2745 | 96.5 | 0.22 | 134 | Good | 546 | Good |
| | 10 | 1980 | 97.8 | 0.98 | 132 | Good | 32 | Good |
| | 11 | 2200 | 97.8 | 0.38 | 124 | Good | 12 | Good |
| Comparative | 1 | 280 | 98.0 | 3.5 | 98 | Poor | 6 | Good |
| Example | 2 | 8540 | 70.0 | 0.25 | >500 | Poor | >10000 | Bad |

(*) The number of the hydroxyl group comprised in the adheisve polymer is 1, a relative ratio of the number of the hydroxyl group comprised in polyrotaxane is α, and a relative ratio of the number of the isocyanate group comprised in the crosslinking agent (C) is β.

TABLE 2

| | | | Isocyanate |
|---|---|---|---|
| | | | based |
| | Acrylic based | | crosslinking |
| | polymer | Polyrotaxane | agent |
| (i) The number of the | 0.000431 | 0.0013 | 0.00457 |
| functional group or the | | | |
| crosslinking group per unit | | | |
| weight [mol/g] | | | |
| (ii) The blending amount | 100 | 9.6 | 10 |
| of Example 1 | | | |
| [parts by weight] | | | |
| (iii) The solid portion | 40.0% | 35.0% | 37.5% |
| (iv) The blending amount | 40 | 3.36 | 3.75 |
| of Example 1 | | | |
| [parts by weight in terms of | | | |
| the soli portion] | | | |
| ((ii) × (iii)/100) | | | |
| (v) The number of the | 0.0172 | 0.0044 | 0.0171 |
| functional group comprised | | | |
| in each component [mol] | | | |
| ((i) × (iv)) | | | |

| | This number is | | | |
|---|---|---|---|---|
| | taken as 1 | α | β | 1 + α − β |
| The number of the | 1 | 0.25 | 0.99 | 0.26 |
| functional group of each | | | | |
| component when the | | | | |
| number of the hydroxyl | | | | |
| group of the polymer is 1 | | | | |
| (the value of (v) of each | | | | |
| component/the value of | | | | |
| (v) of the acrylic based | | | | |
| copolymer) | | | | |

Also, the adhesiveness against the semiconductor wafer formed with the bumps, and the absorbency of the projections were evaluated as described in below.

### (The Absorbency of the Adherend Face Projection)

The adhesive sheet was adhered on the silicon wafer formed with the spherical bumps in a lattice shape having the height of 130 μm and the diameter of 155 μm at pitch of 235 μm (the distance between the centers of the bumps), using the tape laminator Adwill RAD 3510 (made by LINTEC Corporation) at room temperature. Then, it was left for 24 hours at 23° C. and 60% relative humidity. Then, among the space of bumps which corresponds to the diagonal of one lattice (the closest space is 210 μm, among the points on the surface of each bumps), the length (the adhesive layer contact width) of which the adhesive layer being in contact without spacing apart from the silicon wafer was measured by the digital microscope. The longer the contact width is, the more the adhesive agent absorbs the bump.

### Example 12

The adhesive agent mixed with 100 parts by weight of the acrylic based adhesive agent (the copolymer wherein the content of constituting unit derived from butyl acrylate, methyl methacrylate and hydroxyethyl acrylate are 93.5 wt %, 5 wt %, and 1.5 wt % respectively, and the weight average molecular weight of 1,000,000, the glass transition temperature of −48.8° C.); 1.51 parts by weight of the isocyanate based crosslinking agent (TD-75 made by Soken Chemical & Engineering Co., Ltd); and 0.84 parts by weight of polyrotaxane (SeRM Super Polymer A1000 made by Advanced Softmaterials Inc., the solid portion 35 wt %); was coated on the release material (SP-PET381031 made by LINTEC Corporation) so that the thickness after the drying becomes 40 μm, then dried for 1 minute at 100° C., thereby the adhesive layer was formed on the release material. 5 of these adhesive layers were adhered and formed the adhesive layer having the total thickness of 200 μm. The exposed face of this adhesive layer was adhered to the low density polyethylene film having the thickness of 110 μm, thereby the adhesive sheet was produced.

The value of “1+α−β” of the acrylic based adhesive agent is shown in Table 3.

### Example 13

The adhesive sheet was obtained as same as the example 12, except for using the adhesive agent mixing 100 parts by weight of the acrylic based adhesive agent as same as the example 12, and 1.51 parts by weight of the isocyanate based crosslinking agent (TD-75 made by Soken Chemical & Engineering Co., Ltd), and 0.51 parts by weight of polyrotaxane. The value of “1+α−β” of the acrylic based adhesive agent is shown in Table 3.

### Example 14

The adhesive sheet was obtained as same as the example 12, except for using the adhesive agent mixing 100 parts by weight of the acrylic based adhesive agent as same as the example 12, and 1.51 parts by weight of the isocyanate based crosslinking agent (TD-75 made by Soken Chemical & Engineering Co., Ltd), and 0.25 parts by weight of polyrotaxane. The value of “1+α−β” of the acrylic based adhesive agent is shown in Table 3.

### Example 15

The adhesive sheet was obtained as same as the example 12, except for using the adhesive agent mixing 100 parts by weight of the acrylic based adhesive agent as same as the example 12, and 3.0 parts by weight of the isocyanate based crosslinking agent (TD-75 made by Soken Chemical & Engineering Co., Ltd), and 1.68 parts by weight of polyrotaxane. The value of “1+α−β” of the acrylic based adhesive agent is shown in Table 3.

### Reference Example 1

The adhesive sheet was obtained as same as the example 12, except for using the adhesive agent mixing 100 parts by weight of the acrylic based adhesive agent as same as the example 12, and 1.51 parts by weight of the isocyanate based crosslinking agent (TD-75 made by Soken Chemical & Engineering Co., Ltd), and 1.68 parts by weight of polyrotaxane. The value of 1+α−β of the acrylic based adhesive agent is shown in Table 3.

### Comparative Example 3

The adhesive sheet was obtained as same as the example 12, except for using the adhesive agent mixing 100 parts by weight of the acrylic based adhesive agent as same as the example 12, and 0.50 parts by weight of the isocyanate based crosslinking agent (TD-75 made by Soken Chemical & Engineering Co., Ltd). The value of “1+α−β” of the acrylic based adhesive agent is shown in Table 3.

### Comparative Example 4

The adhesive sheet was obtained as same as the example 12, except for using the adhesive agent mixing 100 parts by weight of the acrylic based adhesive agent as same as the example 12, and 1.51 parts by weight of the isocyanate based adhesive agent (TD-75 made by Soken Chemical & Engineering Co., Ltd). The value of 1+α−β of the acrylic based adhesive agent is shown in Table 3.

TABLE 3

| | | | | | Width of | |
|---|---|---|---|---|---|---|
| | Polyrotaxane | Isocyanate | Gel fraction | | contact | Particles |
| | parts by weight | parts by weight | (%) | 1 + α − β | (μm) | (numbers) |
| Example 12 | 0.84 | 1.51 | 64.1 | 0.67 | 158.8 | 69 |
| Example 13 | 0.51 | 1.51 | 77.7 | 0.60 | 158.8 | 142 |
| Example 14 | 0.25 | 1.51 | 88.8 | 0.50 | 131.6 | 126 |
| Example 15 | 1.68 | 3.00 | 79.5 | 0.50 | 159.3 | 98 |
| Reference 1 | 1.68 | 1.51 | 15.9 | 0.83 | 165.5 | 8563 |
| Comparative | — | 0.50 | 35.4 | — | 163.1 | 5743 |
| Example 3 | | | | | | |
| Comparative | — | 1.51 | 94.5 | — | 101.3 | 21 |
| Example 4 | | | | | | |

1. An adhesive sheet for wafer processing, comprising:
a base film; and
an adhesive layer formed thereon,
wherein said adhesive layer includes an adhesive polymer (A) and polyrotaxane (B) having at least two cyclic molecules and a linear-chain molecule passing through an opening of the cyclic molecules wherein the linear-chain molecule has blocking groups at both ends thereof, and
wherein the adhesive polymer (A) and the cyclic molecule of polyrotaxane (B) are bonded to form a crosslinked structure.

2. The adhesive sheet for wafer processing as set forth in claim 1, wherein said adhesive polymer (A) has reactive functional group, said cyclic molecule has a reactive functional group, and the reactive functional group of said adhesive polymer (A) and the reactive functional group of said cyclic molecule forms a crosslinked structure by binding directly or indirectly.

3. The adhesive sheet for wafer processing as set forth in claim 1, wherein storage elasticity at 25° C. of said adhesive layer is 2.5 MPa or less.

4. The adhesive sheet for wafer processing as set forth in claim 1, wherein an adhesive force when releasing from a silicon wafer mirror face while the sheet being cut into a size having a width of 25 mm is 5000 mN/25 mm or less.

5. The adhesive sheet for wafer processing as set forth in claim 2, wherein each of the reactive functional group of said adhesive polymer (A) and polyrotaxane (B) forms the crosslinked structure by binding via a crosslinking agent (C) comprising a crosslinking group capable of reacting with the reactive functional group of said adhesive polymer (A) and with the reactive functional group of said polyrotaxane (B).

6. The adhesive sheet for wafer processing as set forth in claim 5, wherein the reactive functional group of said adhesive polymer (A) and the reactive functional group of polyrotaxane are the same functional group, and
when the number of the reactive functional group comprised in the adhesive polymer (A) is taken as 1, a relative ratio α of the number of the reactive functional group comprised in polyrotaxane (B) to the number of the reactive functional group comprised in the adhesive polymer (A) is taken as α, and a relative ratio β of the number of the crosslinking group comprised in the crosslinking agent (C) to the number of the reactive functional group comprised in the adhesive polymer (A) is taken as β, then the adhesive layer satisfies a relation of 1+α−β≦1.2.

7. The adhesive sheet for wafer processing as set forth in claim 5, wherein the reactive functional group of said adhesive polymer (A) and polyrotaxane (B) are hydroxyl group, and the crosslinking group of said crosslinking agent (C) is isocyanate group.

8. The adhesive sheet for wafer processing as set forth in claim 1, wherein a breaking elongation is 100% or more when a thickness of said adhesive layer is 1 mm.

9. The adhesive sheet for wafer processing as set forth in claim 1, wherein a gel fraction of said adhesive layer is 90% or more.

10. A method for processing a semiconductor wafer comprising:
adhering a circuit surface of the semiconductor wafer formed with a circuit on a surface to the adhesive layer of the adhesive sheet for wafer processing as set forth in claim 1, and
backside processing of the semiconductor wafer.

11. The method for processing the semiconductor wafer as set forth in claim 10 wherein the backside processing of said semiconductor wafer is a backside grinding.

12. A method for processing a semiconductor wafer comprising:
adhering the semiconductor wafer formed with the circuit on a surface to the adhesive layer of the adhesive sheet for wafer processing as set forth in claim 1, and
dicing the semiconductor wafer.

13. A production method of a semiconductor chip, comprising:
forming a groove having a depth of cut shallower than a wafer thickness from a semiconductor wafer surface formed with a circuit with a bump,
adhering the adhesive sheet as set forth in claim 1 to said circuit formed face,
thinning the wafer thickness by carrying out a backside grinding of said semiconductor wafer, and
dividing into each chip and picking up the chip.

14. An adhesive sheet for semiconductor wafer processing comprising:
a base film and an adhesive layer formed on one side thereof, wherein a thickness of the adhesive layer is 100 to 300 μm,
said adhesive layer is formed of a crosslinked structure by binding adhesive polymer (A) and polyrotaxane (B) via a crosslinking agent (C), said adhesive polymer (A) and polyrotaxane (B) has same reactive functional group, and
when the number of the reactive functional group comprised in the adhesive polymer (A) is taken as 1, a relative ratio α of the number of the reactive functional group comprised in polyrotaxane (B) to the number of the reactive functional group comprised in the adhesive polymer (A) is taken as α, and a relative ratio β of the number of the crosslinking group comprised in the crosslinking agent (C) to the number of the reactive functional group comprised in the adhesive polymer (A) is taken as β, then the adhesive layer satisfies a relation of 1+α−β≦0.8,
wherein adhesive polymer (A) comprises an adhesive polymer comprising a reactive functional group and
wherein polyrotaxane (B) comprises a polyrotaxane having at least two cyclic molecules and a linear-chain molecule passing through opening of the cyclic molecules wherein the linear-chain molecule has blocking groups at both ends thereof.

15. The adhesive sheet for semiconductor wafer processing as set forth in claim 14, wherein a gel fraction of said adhesive layer is 40% or more.

16. The adhesive sheet for semiconductor wafer processing as set forth in claim 14, wherein said adhesive layer has multilayered structure.

17. The adhesive sheet for semiconductor wafer processing as set forth in claim 14, wherein said reactive functional group is hydroxyl group, and said crosslinking agent (C) is isocyanate based crosslinking agent.

18. The adhesive sheet for semiconductor wafer processing as set forth in claim 14 used for a grinding of a backside of the semiconductor wafer.

19. The adhesive sheet for semiconductor wafer processing as set forth in claim 18, wherein a substance of said semiconductor wafer is provided with a projection having a height of 50 μm or higher on a surface.

20. The production method of a thinned semiconductor wafer comprising:
adhering the adhesive sheet for semiconductor wafer processing as set forth in claim 14 to a projection face of the semiconductor wafer provided with projections on one side, and
grinding one face of the semiconductor wafer which is not adhered with said adhesive sheet for semiconductor wafer processing.

21. The production method of the thinned semiconductor wafer as set forth in claim 20, wherein a height of said projection is 50 μm or more.
